(19) United States
(12) Patent Application Publication
(10) Pub. No.: US 2007/0007666 A1
(43) Pub. Date: Jan. 11, 2007

(54) Substrate for manufacturing semiconductor device, semiconductor device manufacturing method

(75) Inventor: Hideo Imai, Shimosuwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/478,488

(22) Filed: Jun. 29, 2006

(30) Foreign Application Priority Data
Jul. 7, 2005 (JP) 2005-198494

(51) Int. Cl. H01L 23/48

(52) U.S. Cl. 257/783

(57) ABSTRACT

A substrate for manufacturing semiconductor device includes a wafer; a plurality of semiconductor elements formed on the wafer; a bump arranged in each peripheral section of the semiconductor elements; an alignment mark arranged in the each peripheral section of the semiconductor elements; and an adhesive layer formed on the semiconductor elements. The adhesive layer has a greater thickness in each central section of the semiconductor elements where the bump is not provided than in the each peripheral section of the semiconductor elements.

### CROSS-REFERENCE TO RELATED APPLICATION

This application claims priority to Japanese Patent Application No. 2005-198494, filed Jul. 7, 2005, the contents of which are incorporated herein by reference.

### BACKGROUND

1. Technical Field

The present invention relates to a substrate for manufacturing semiconductor device, and a semiconductor device manufacturing method using the substrate.

2. Related Art

Conventionally, a flip-chip packaging method using an adhesive film such as an anisotropic conductive film and a nonconductive film is generally performed by supplying the adhesive film on a substrate side and connecting a bumped IC over it by hot-pressure bonding.

However, due to recent demands for high-density packaging, in view of desires to reduce the overflow amount of the adhesive film as much as possible, mount other components near the IC, and reduce the packaging region, packaging methods are being proposed which supply an adhesive film on a wafer side beforehand and dice it to make the adhesive film the same size as the IC (e.g., see Japanese Unexamined Patent Publication, First Publication No. 2001-237268).

According to this method, when aligning the substrate and the IC, the IC side detects an alignment mark through the adhesive film. However, the following problems arise in such cases.

Normally, the thickness of the adhesive film is determined after considering the height of the bump on the IC side and the thick portion (gap between the IC and the substrate) of wiring on the substrate side. For example, in chip-on-glass (COG) packaging on a glass substrate, the wiring on the glass substrate side hardly need to be considered since it has an Angstrom order of thickness, and the thickness of the adhesive film can be determined after considering only the height of the bump. On the other hand, in chip-on-board (COB) packaging, the adhesive film must have greater thickness to match the thickness of the wiring (several μm). In this case there is a problem that, when aligning, the camera recognition of the flip-chip bonder deteriorates in proportion to the increased thickness of the adhesive film.

### SUMMARY

An advantage of some aspects of the invention is to provide a substrate for manufacturing semiconductor device which enables a semiconductor device to be easily and reliably manufactured, and a method of manufacturing a semiconductor device using the substrate.

A substrate for manufacturing semiconductor device according to an aspect of the invention includes: a wafer; a plurality of semiconductor elements formed on the wafer; a bump arranged in each of peripheral sections of the semiconductor elements; an alignment mark arranged in each of the peripheral sections of the semiconductor elements; and an adhesive layer formed on the semiconductor elements, the adhesive layer having, in each of central sections of the semiconductor elements where the bump is not provided, a greater thickness than that in each of the peripheral sections of the semiconductor elements.

According to this substrate for manufacturing semiconductor device, of the adhesive layer formed on the wafer, the adhesive layer positioned in each of the central sections of the semiconductor elements where no bumps are provided has a greater thickness than the adhesive layer in each of the peripheral sections of the semiconductor elements where the bump is provided, and the adhesive layer protrudes at each of the central sections. Therefore, when packaging the substrate including the semiconductor element with a wiring substrate having a predetermined wiring pattern, the protruding section is arranged facing the wiring substrate such as to achieve reliable connection in the protruding sections. Since the adhesive layer has a less thickness in each of the peripheral sections, namely the regions where the bump is formed, than in each of the central sections, the detectability (visibility) of the alignment mark arranged in each of the peripheral sections is unlikely to deteriorate due to the presence of the adhesive layer. As a result, according to the substrate for manufacturing semiconductor device of the invention, the reliability of the connection when packaging the semiconductor element with a wiring substrate such as that mentioned above, and the detectability (visibility) of the mark at the time of aligning, can be satisfactorily achieved. When the wiring of the wiring substrate is particularly thick, there is a problem that if the adhesive layer is formed with a uniform thickness in consideration of the visibility of the alignment marks, a region (gap) unfilled by the adhesive layer will be formed between the wiring substrate and the semiconductor element, causing a reduction in the adhesion and a consequent reduction in the connection reliability. However, when the adhesive layer is formed thickly (i.e., in a convex shape) in the central section in the manner of the invention, it becomes possible to completely fill such a gap, thereby increasing the adhesion and maintaining a reliable connection.

In the substrate for manufacturing semiconductor device, the adhesive layer can include a first adhesive layer formed with a uniform thickness on the semiconductor elements, and a second adhesive layer formed over the first adhesive layer in each of the central sections of the semiconductor elements. When laminated in this manner, the adhesive layers having the thickness relationship mentioned above can be formed easily. Specifically, the second adhesive layer can be formed selectively after forming the first adhesive layer, or the second adhesive layer can be selectively formed by photolithography after forming the first adhesive layer, or another method may be used.

In the substrate for manufacturing semiconductor device, it is acceptable that, of the first adhesive layer and the second adhesive layer, only the first adhesive layer contains conductive particles. When only the first adhesive layer contains conductive particles, the space between the semiconductor element and the wiring substrate can be insulated, and the bump can be reliably electrically connected to the wiring.

A method of manufacturing semiconductor device according to an aspect of the invention includes: forming a plurality of semiconductor elements on a wafer, a bump and an alignment mark arranged in each of peripheral sections of the semiconductor elements; forming an adhesive layer on the semiconductor elements, the adhesive layer having, in each of central sections of the semiconductor elements where the bump is not provided, a greater thickness than that in each of the peripheral sections of the semiconductor elements; cutting the wafer to obtain a plurality of semiconductor element pieces corresponding the semiconductor elements; and packaging each of the semiconductor element pieces on a wiring substrate with the adhesive layer in between, the wiring substrate including a wiring of a predetermined pattern. The semiconductor element package using this substrate for manufacturing semiconductor device is remarkably reliable and has excellent connection stability.

In the step of cutting, cutting can be performed in peripheral sections of the semiconductor element. During cutting, by simultaneously dicing the wafer and the adhesive layer, the sizes of the semiconductor element and the adhesive layer become identical (i.e., the adhesive layer covers the entire face of the semiconductor element), making it possible to mount other electronic components in the peripheral sections of the semiconductor element and thereby obtain high-density packaging.

Furthermore in the step of packaging, the semiconductor element piece can be packaged to the wiring substrate in a state where the thick section (protruding section) of the adhesive layer formed in the semiconductor element piece is arranged facing the section of the wiring substrate where no wiring is provided. In this case, the bump and the wiring of the wiring substrate are connected in the peripheral section, and the semiconductor element is reliable affixed to the wiring substrate without forming a gap, thereby achieving a stable connection.

### BRIEF DESCRIPTION OF THE DRAWINGS

FIG. 1 is a plan schematic view of a substrate for manufacturing semiconductor device according to an embodiment of the invention.

FIG. 2 is a cross-sectional schematic view taken along the line A-A′ of FIG. 1.

FIGS. 3A and 3B are cross-sectional schematic views of examples of manufacturing steps of a substrate for manufacturing semiconductor device.

FIG. 4 is a cross-sectional schematic view of an example of a cutting step of a substrate for manufacturing semiconductor device.

FIG. 5 is a cross-sectional schematic view of an example of a packaging step.

FIG. 6 is a cross-sectional schematic view of a semiconductor device manufactured using the substrate for manufacturing semiconductor device of FIG. 1.

FIG. 7 is an explanatory view of effects of the semiconductor device of FIG. 6.

FIG. 8 is a cross-sectional schematic view of a modification of a packaging step.

FIG. 9 is a cross-sectional schematic view of a modification of a substrate for manufacturing semiconductor device.

### DESCRIPTION OF EXEMPLARY EMBODIMENTS

An embodiment of the invention will be explained with reference to the drawings. In each of the drawings used in the explanation below, the sizes of the members are changed as appropriate to make them large enough to be recognized.

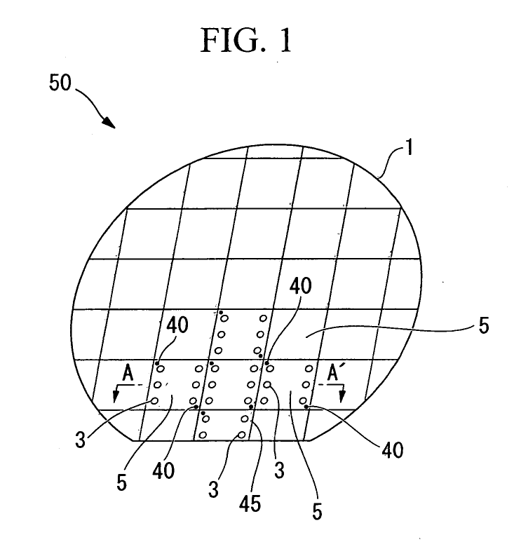

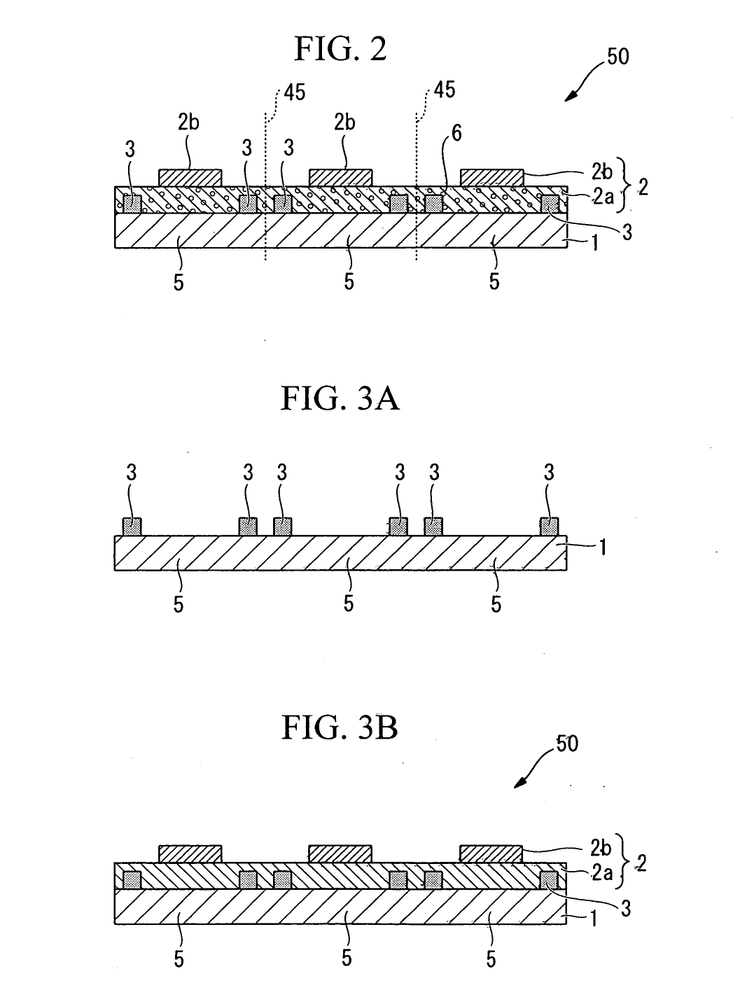

FIG. 1 is a plan schematic view of a substrate for manufacturing semiconductor device according to the invention, and FIG. 2 is a cross-sectional schematic view taken along the line A-A′ of FIG. 1. A substrate for manufacturing semiconductor device 50 of FIGS. 1 and 2 has a wafer 1 including a plurality of semiconductor elements 5 as its substrate. The wafer 1 is formed using silicon.

Bumps 3 are formed on a surface of the wafer 1. Specifically, the bumps 3 are arranged in each peripheral section of the semiconductor elements 5, and each semiconductor element 5 is formed into peripheral-type. An adhesive layer 2 is disposed on the wafer 1 including the bumps 3. The adhesive layer 2 includes a first adhesive layer 2a which is provided in a sheet form of uniform thickness over the entire surface of the wafer 1, and an island-shaped second adhesive layer 2b which is formed in a predetermined pattern on the first adhesive layer 2a.

The adhesive layer 2 includes a thermosetting adhesive material which becomes adhesive after hot pressing. In this embodiment, different types of adhesive materials are used for the first adhesive layer 2a and the second adhesive layer 2b. As the thermosetting adhesive material, for example, an adhesive whose chief material is an epoxy resin, an acrylic resin, or the like, can be used as the first adhesive layer 2a. For example, an epoxy resin can be used as the first adhesive layer 2a and an acrylic resin for the second adhesive layer 2b. If the adhesive layer 2 is to have a protruding shape due to the presence of the second adhesive layer 2b, there are no particular limitations on the material used, and the same type of adhesive material can be used for the first and second adhesive layers 2a and 2b.

The second adhesive layer 2b is arranged in a region of each semiconductor element 5 where there are no bumps 3, that is, in a center side region of each semiconductor element 5. By selectively forming the second adhesive layer 2b in the center sides (central sections) of the semiconductor elements 5 in this manner, the adhesive layer 2 is formed thickly in the center sides of the semiconductor elements 5 where there are no bumps 3, beside the peripheral sections where the bumps 3 are arranged. That is, in each semiconductor element 5, the adhesive layer 2 is formed thinly (e.g., 20 μm) in the peripheral section of the semiconductor element 5 and thickly (e.g., 30 μm) in the center side of the semiconductor element 5. The resulting shape of the adhesive layer 2 has protruding sections in the center sides of the semiconductor elements 5.

Of the first adhesive layer 2a and the second adhesive layer 2b, only the first adhesive layer 2a includes conductive particles 6. When attaching the substrate for manufacturing semiconductor device 50 to a wiring substrate and the like, the inclusion of these conductive particles 6 enables the bumps 3 to be electrically connected to the wiring.

While gold bumps formed by plating are used here the bumps 3, bumps may instead be formed by nickel and subsequently plating gold.

A method of manufacturing the substrate for manufacturing semiconductor device 50 will be explained with referring to FIGS. 3A and 3B.

In FIG. 3A, the bumps 3 are formed on the wafer 1 in a predetermined pattern, and a plurality of semiconductor elements 5 of identical configuration are formed. The wafer is made of silicon semiconductor crystal. While gold bumps are here formed by plating, ball bumps may be used instead.

The adhesive layer 2 is then formed on the wafer 1 (FIG. 3B). The following method is used to form the adhesive layer 2 with a convex pattern.

A film resin of epoxy resin is laminated over the entire face of the wafer 1 to form the first adhesive layer 2a. An adhesive film of acrylic resin is then arranged in a predetermined base material for formation in each of the semiconductor elements 5, and is laminated using this base material in one block.

When forming the adhesive layer 2 by laminating in this manner, the same material can be used as adhesive material for the first adhesive layer 2a and the second adhesive layer 2b. For example, after forming a film resin of epoxy resin in a sheet form over their entire faces of the wafer 1, a piece of film resin can be formed in a predetermined pattern over the epoxy resin. Laminating is preferably performed in a state of low pressure. In a state of low pressure, it is possible to prevent failure caused by infiltration of air bubbles between the wafer 1 and the adhesive layer 2.

Alternatively, after forming the first adhesive layer 2a in a sheet form over their entire faces of the wafer 1, the entire face of the first adhesive layer 2a is covered with a second adhesive layer 2b in a sheet form of photosensitive resin, and the adhesive layer 2 is given a protruding shape by patterning with exposure. In this case, the material of the first adhesive layer 2a must be light-resistant when exposing the second adhesive layer 2b. It is also necessary to use different adhesive material for the first adhesive layer 2a and the second adhesive layer 2b.

As shown for example in FIG. 9, when the adhesive layer 2 is formed from a single material, a protruding shape can be obtained by mask etching using photolithography. Specifically, after covering the entire face of the wafer 1 with a sheet form of adhesive material, the central section of each semiconductor element 5 (i.e. the section where the protruding shape is desired to be formed) is masked, and the adhesive layer 2 having the configuration shown in FIG. 9 can be formed by etching of the adhesive material.

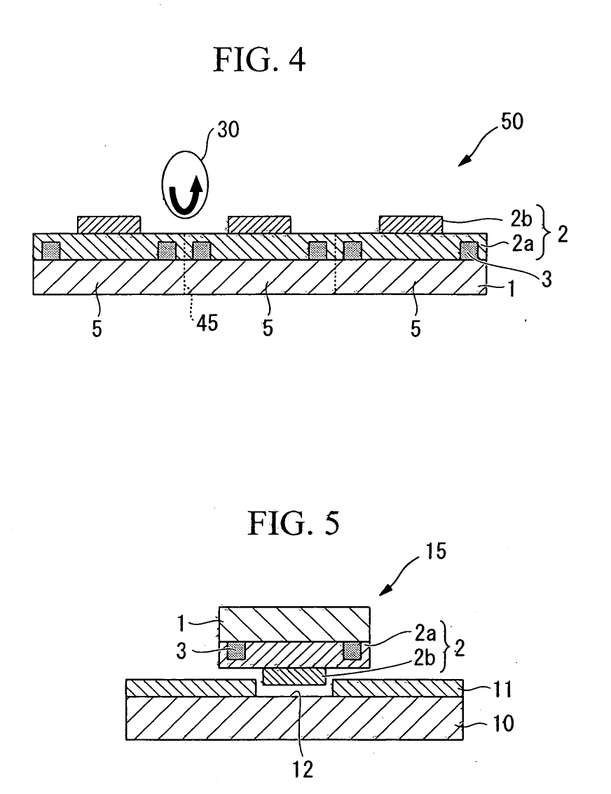

Subsequently, a method of manufacturing a semiconductor device using the substrate for manufacturing semiconductor device 50 will be explained with reference to FIGS. 4 and 5.

Firstly, the substrate for manufacturing semiconductor device 50 is diced as shown in FIG. 4. Specifically, a diamond cutter 30 is used to cut the wafer 1 and the adhesive layer 2 along boundary lines (cutting lines) 45 of the semiconductor elements 5 in a single operation. This dicing obtains each of semiconductor element pieces 15 such as that shown in FIG. 5. The boundary lines 45 are not actually drawn; they refer to hypothetical cutting lines which are unambiguously determined by alignment with alignment marks 40 (see FIG. 1).

The adhesive layer 2 is formed on the each semiconductor element piece 15 such as to cover the wafer 1 including the bumps 3. In the adhesive layer 2, the second adhesive layer 2b is formed over the first adhesive layer 2a. Consequently, the adhesive layer 2 is thin in the peripheral section including the bumps 3 and thick in the center section, as described above.

As shown in FIG. 5, the semiconductor element piece 15 is then mounted on a wiring substrate 10 which includes wiring 11 having a predetermined pattern. The wiring substrate 10 and the semiconductor element piece 15 are affixed together with the adhesive layer 2 in between.

Specifically, after aligning the wiring substrate 10 and the semiconductor element piece 15, a region (non-wired region) 12 of the wiring substrate 10 where no wiring 11 is formed is arranged facing a protruding section of the adhesive layer 2 (i.e. the second adhesive layer 2b), and the wiring substrate 10 and the semiconductor element piece 15 are affixed together in that state. Alignment is performed while referring to the alignment marks 40 shown in FIG. 1. The wiring substrate 10 and the semiconductor element piece 15 are affixed together by applying heat while they are touching, thereby melting the adhesive layer 2.

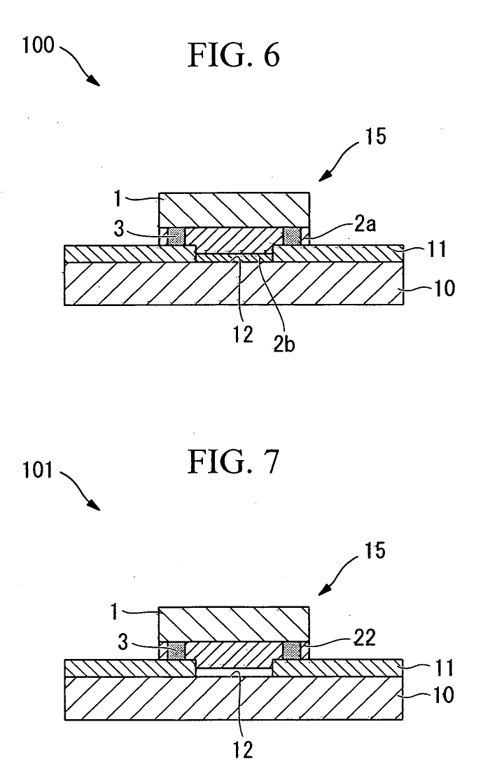

This packaging method manufactures a semiconductor device 100 in which the semiconductor element 15 is packaged as shown in FIG. 6. The semiconductor device 100 has an excellent electrical connection between the bumps 3 and the wiring 11, and excellent adhesion between the substrate 10 and the semiconductor element 15.

When the wiring 11 of the wiring substrate 10 is comparatively thick, if an adhesive layer 22 having a uniform thickness is formed in consideration of the detectability (visibility) of the alignment marks 40 (see FIG. 1) as shown in FIG. 7, there is a possibility that a region (gap) unfilled by the adhesive layer 22 will be formed between the wiring substrate 10 and the semiconductor element 15. If the packaging is such that a gap is formed between the semiconductor element 15 and the wiring substrate 10 in this way, the gap may reduce the adhesion and the reliability of the connection. However, according to the semiconductor device 100 manufactured by the method described above (see FIG. 6), the protruding shape of the second adhesive layer 2b ensures that no gap is formed between the semiconductor element 15 and the wiring substrate 10 and that they can be reliably affixed together.

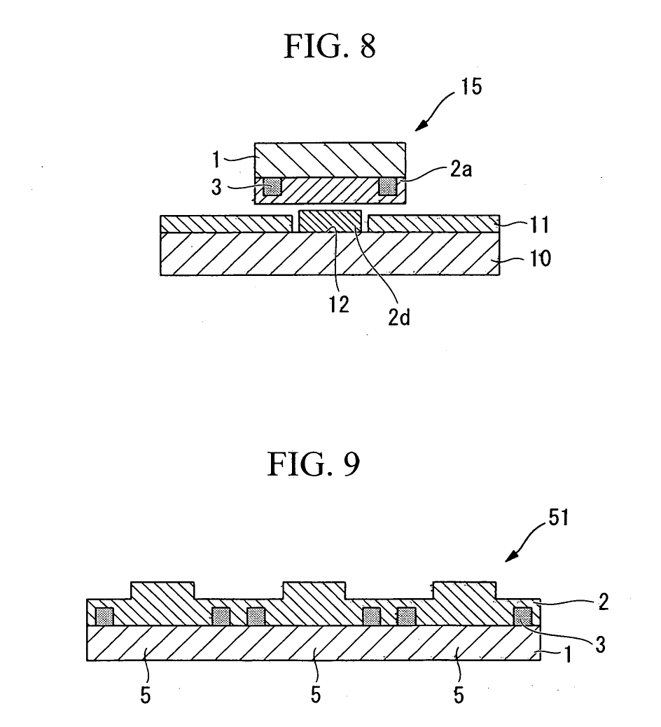

When the wiring 11 is comparatively thick as described above, a method such as that shown in FIG. 8 can be used to manufacture the semiconductor element 15 which achieves electrical connection and substrate-element connection. A second adhesive layer 2d is provided in the region 12 of the wiring substrate 10 where no wiring 11 is formed (the second adhesive layer 2d having a greater thickness than the wiring 11). In addition, a first adhesive layer 2a of uniform thickness is formed on the semiconductor element 15, and the second adhesive layer 2d and the first adhesive layer 2a are affixed facing each other. This packaging method also avoids forming a gap in the region 12, and can prevent failure caused by a gap between the substrate and the element.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A substrate for manufacturing semiconductor device, comprising:
a wafer;
a plurality of semiconductor elements formed on the wafer;
a bump arranged in each of peripheral sections of the semiconductor elements;
an alignment mark arranged in each of the peripheral sections of the semiconductor elements; and
an adhesive layer formed on the semiconductor elements, the adhesive layer having, in each of peripheral central sections of the semiconductor elements where the bump is not provided, a thickness greater than in that each of the peripheral sections of the semiconductor elements.

2. The substrate for manufacturing semiconductor device according to claim 1, wherein the adhesive layer includes a first adhesive layer formed with a uniform thickness on the semiconductor elements, and a second adhesive layer formed over the first adhesive layer in each of the central sections of the semiconductor elements.

3. The substrate for manufacturing semiconductor device according to claim 1, wherein, of the first adhesive layer and the second adhesive layer, only the first adhesive layer contains conductive particles.

4. A manufacturing method for semiconductor device comprising:
forming a plurality of semiconductor elements on a wafer, a bump and an alignment mark arranged in each of peripheral sections of the semiconductor elements;
forming an adhesive layer on the semiconductor elements, the adhesive layer having, in each of central sections of the semiconductor elements where the bump is not provided, a thickness greater than that in each of the peripheral sections of the semiconductor elements;
cutting the wafer to obtain a plurality of semiconductor element pieces corresponding the semiconductor elements; and
packaging each of the semiconductor element pieces on a wiring substrate with the adhesive layer in between, the wiring substrate including a wiring of a predetermined pattern.
